(19) United States
(12) Patent Application Publication
(10) Pub. No.: US 2025/0022910 A1
(43) Pub. Date: Jan. 16, 2025

(54) SEMICONDUCTOR STRUCTURES GROWN ON HETERO-INTERFACE WITHOUT ETCH DAMAGE

(71) Applicant: Snap Inc., Santa Monica, CA (US)

(72) Inventor: Tao Wang, Sheffield (GB)

(21) Appl. No.: 18/900,266

(22) Filed: Sep. 27, 2024

Related U.S. Application Data
(63) Continuation of application No. 17/250,997, filed on Apr. 9, 2021.

(30) Foreign Application Priority Data
Oct. 9, 2018 (GB) 1816455.8

(51) Int. Cl. H01L 27/15; H01L 33/00; H01L 33/06; H01L 33/32; H01L 33/38

(52) U.S. Cl. CPC H01L 27/156; H01L 33/0075; H01L 33/06; H01L 33/32; H01L 33/387; H01L 2933/0016

(57) ABSTRACT

An array of semiconductor structures is grown on a hetero-interface barrier layer by forming successive semiconductor layers within holes formed through a dielectric layer deposited above the hetero-interface barrier layer. The hetero-interface forms a two dimensional charge carrier gas. Each semiconductor structure is grown within one of the holes and includes at least one LED active layer between an n-type semiconductor layer and a p-type semiconductor layer. The bottom one of the two semiconductor layers has the same conductivity type as the barrier layer on which it is formed. The hetero-interface is defined between the barrier layer and a buffer layer. The barrier layer and buffer layer can be formed from GaN, AlGaN, and/or InGaN of varying concentrations. The two dimensional charge carrier gas can be a 2D electron gas or a 2D hole gas.

### CLAIM OF PRIORITY

This application is a continuation of U.S. patent application Ser. No. 17/250,997, filed on Apr. 9, 2021, which is a U.S. national-phase application filed under 35 U.S.C. § 371 from International Application Serial No. PCT/GB2019/052843, filed on Oct. 8, 2019, and published as WO 2020/074875 on Apr. 16, 2020, which claims the benefit of priority to United Kingdom Patent Application Serial No. 1816455.8, filed on Oct. 9, 2018, each of which is incorporated herein by reference in its entirety.

### FIELD OF THE INVENTION

The present invention relates to light emitting diodes (LEDs) and to methods of producing LED arrays. It has particular application in arrays of LEDs on the micrometer scale.

### BACKGROUND TO THE INVENTION

There is a significantly increasing demand for the development of III-nitride light emitting diodes (LEDs) on a micrometre scale, also referred to as micro-sized LEDs or micro-LEDs (μLEDs). Micro-LEDs are the key components for new generation displays and visible light communication (VLC) applications. III-nitride μLEDs exhibit a number of unique features for display applications compared with organic light-emitting diodes (OLEDs) and liquid crystal displays (LCDs). Unlike LCDs, III-nitride microdisplays, where μLEDs are the major components, are self-emissive. Monochromatic displays using μLEDs exhibit high resolution, high efficiency, and high contrast ratio. OLEDs are typically operated at a current density which is several orders of magnitude lower than semiconductor LEDs in order to maintain a reasonable lifetime. As a consequence, the luminance of OLEDs is relatively low, typically 3000 cd/m² for a full colour display, while III-nitride μLEDs exhibit high luminance of above 10⁵ cd/m². Of course, III-nitride μLEDs intrinsically exhibit long operation lifetime and chemical robustness in comparison with OLEDs. Therefore, it is expected that III-nitride μLEDs could potentially replace LCD and OLEDs for high resolution and high brightness display in a wide range of applications in the near future, such as smart phones. In addition to display applications, μLEDs exhibit significantly reduced junction capacitance as a result of reduced dimension compared with broad-area LEDs, and thus potentially lead to high-speed transmission with a GHz modulation bandwidth in VLC applications.

Currently, III-nitride μLEDs are exclusively fabricated by means of combining a standard photolithography technique and subsequent dry etching process on a standard III-nitride LED wafer, which is similar to the fabrication of conventional broad-area LEDs with a typical device area of 300 μm×300 μm or even larger dimension (Z. Y. Fan, J. Y. Lin and H. X. Jiang, J. Phys. D: Appl. Phys. 41, 094001 (2008); H. X. Jiang and J. Y. Lin, Optical Express 21, A476 (2013)). The only major difference in device fabrication between broad-area LEDs and μLEDs is the device dimension. Typically, the diameter of a μLED ranges from 50 μm down to several micrometres.

There are a number of fundamental issues in current approaches to the fabrication of III-nitride μLEDs. Firstly, drying etching processes, such as inductively-coupled plasma (ICP) dry etching techniques, have been widely used to define both broad area LED mesas and μLED mesas in the semiconductor industry. Therefore, surface and sidewall damage introduced by dry etching processes significantly enhances the non-radiative recombination rate (F. Olivier, A. Daami, C. Licitra and F. Templier, Appl. Phys. Lett. 111, 022104 (2017); S. S. Konoplev, K. A. Bulashevich, and S. Y. Karpov, Phys. Status Solidi A 215, 1700508 (2017); W. Chen, G. Hu, J. Lin, J. Jiang, M. Liu, Y. Yang, G. Hu, Y. Lin, Z. Wu, Y. Liu and B. Zhang, Appl. Phys. Express 8, 032102 (2015); C.-M. Yang, D.-S. Kim, Y. S. Park, J.-H. Lee, Y. S. Lee and J.-H. Lee, Opt. Photonics J. 2, 185 (2012); Y. Zhang, E. Guo, Z. Li, T Wei, J. Li, X. Ye and G. Wang, IEEE Photonics Technol. Lett. 24, 243 (2012); P. Zuo, B. Zhao, S. Yan, G. Yuc, H. Yang, Y. Li, H. Wu, Y. Jiang, H. Jia, J. Zhou and H. Chen, Opt. Quantum Electron. 48, 1 (2016). This issue becomes more severe in LEDs with reduced dimensions, especially for μLEDs with a large surface area to bulk volume ratio. So far, all reports show that the peak external quantum efficiency (EQE) decreases as the dimension of the μLED decreases (D. Hwang, A. Mughal, C. D. Pynn, S. Nakamura and S. P. DenBaars, Appl. Phys. Express 10, 032101 (2017); P. Zuo, B. Zhao, S. Yan, G. Yue, H. Yang, Y. Li, H. Wu, Y. Jiang, H. Jia, J. Zhou and H. Chen, Opt. Quantum Electron. 48, 1 (2016); F. Olivier, S. Tirano, L. Dupré, B. Aventurier, C. Largeron and F. Templier, J. Lumin. 191, 112 (2017); P. Tian, J. J. D. McKendry, J. Herrnsdorf, S. Watson, R. Ferreira, I. M. Watson, E. Gu, A. E. Kelly and M. D. Dawson, Appl. Phys. Lett. 105, 171107 (2014)).

This decrease is due to surface recombination and the sidewall damage of the mesa from the dry etching, which creates sidewall defects for non-radiative recombination. Although sidewall passivation using dielectric materials can to some degrees reduce the effect of plasma induced damage in LEDs, the improvement is marginal even when an advanced atomic layer deposition (ALD) technique, instead of a standard plasma-enhanced chemical vapor deposition (PECVD) technique, is used for surface passivation.

Secondly, current approaches, which involve the utilisation of the combination of a standard photolithography technique and subsequent dry etching processes, normally lead to the waste of huge areas of an epiwafer. For example, in order to fabricate μLED arrays with a diameter of 12 μm and a pitch distance of 15 μm (it is very challenging to further reduce the pitch distance with current photolithograph techniques), 50% material of an epiwafer needs to be etched away, meaning that 50% of the epiwafer has been wasted.

Thirdly, future smart displays including micro displays and VLC need to be operated with an ultra-high response speed. Therefore, an electrical channel with an ultrafast speed is necessary for the interconnection between LED driving transistors and individual LED components.

Current μLED arrays are electrically connected through the n-GaN of a III-nitride LED wafer, where the typical fabrication procedure for μLED arrays is to use dry-etching processes to etch the LED wafer down to the n-GaN which is the only electrical channel to connect all μLEDs.

Therefore, it is desirable to develop different approaches to the growth and then the fabrication of μLED arrays in order to address these issues. In order to meet industry requirement, any new approaches will have to be built on a scalable base.

### SUMMARY OF THE INVENTION

The present invention provides a method of producing a light emitting diode (LED) array, the method comprising: forming a semiconductor layer of group III nitride material; forming a dielectric mask layer over the semiconductor layer, the dielectric mask layer having an array of holes through it each exposing an area of the semiconductor layer; and growing an LED structure in each of the holes.

The LED structures may be grown on the exposed areas of the semiconductor layer. The growth will generally be in the upward direction, as growth from the dielectric sidewalls of the holes will not occur. The upward growth of the LED structures within the holes may therefore result in a layered LED structure with each of the layers being generally flat or planar, and of substantially constant thickness.

The semiconductor layer may be formed on a substrate, for example of group III nitride, such as GaN, or of sapphire, silicon (Si) silcon carbide (SiC), or of glass.

The step of growing an LED structure in each of the holes may comprise growing an n-type layer, at least one active layer, and a p-type layer in each of the holes. The at least one active layer may be between the n-type and p-type layers. The at least one active layer may comprise at least one quantum well layer, and may comprise multiple quantum well layers. These may be formed, for example, of InGaN or another suitable group III nitride material. The n-type and p-type layers may also be of group III nitride material, such as GaN, InGaN or AlGaN.

The at least one active layer may have an upper surface which is below the top of the dielectric layer. Where there is only one quantum well layer, the upper surface is the upper surface of that quantum well layer. Where there are a plurality of quantum well layers, the upper surface is the upper surface of the uppermost quantum well layer. The upward direction may be defined as the direction of growth of the semiconductor layer and/or of the LED structures.

The step of forming the dielectric mask layer may comprise growing a layer of dielectric material, forming a mask over the dielectric mask layer, for example using photolithography, and etching the array of holes into the layer of dielectric material using the mask. Alternatively the dielectric layer may be grown around the areas which then form the holes, for example using a mask, formed by photolithography with subsequent growth and/or etching, during growth of the dielectric layer.

The method may further comprise etching each of the exposed areas of the semiconductor layer before growing the LED structure in each of the holes.

The semiconductor layer may provide a common contact to all of the LED structures.

The semiconductor layer may be doped. For example, it may comprise a single layer of n-type or p-type group III nitride material. Alternatively, the semiconductor layer may comprise first and second sub-layers with a hetero-interface between them arranged to form a two dimensional charge carrier gas at the hetero-interface. The sub-layers may form a buffer layer and a barrier layer. The two dimensional charge carrier gas may, for example, be a two dimensional electron gas (2DEG). A two dimensional hole gas (2DHG) could also be used, but typically these have lower charge carrier density and/or mobility. It is well known that a hetero-structure comprising, for example, a layer of GaN and a layer of AlGaN or InGaN, or more generally two layers of AlGaN with different Al contents or two layers of InGaN with different In contents, can form a 2DEG at the interface between the two layers, with the electron density in the 2DEG varying with a number of factors including the Al content of the AlGaN layer or the In content of the InGaN layer. Other group III nitride hetero-interfaces can be used with the same effect.

The method may further comprise forming one or more contact layer areas over the LED structures. The or each contact layer area may extend over at least one of the LED structures, so as to be in electrical contact with the at least one of the LED structures. The contact layer areas may be electrically isolated from each other.

The holes, and hence the LED structures, may be arranged in a regular array. The array may be a square array, or it may be a rectangular array or a hexagonal array. The array may have a pitch, i.e. a distance between the centres of each closest pair of holes or LEDs, of from 4 μm to 500 μm. The holes, and hence also the LED structures, may have a maximum diameter of from 1 to 500 μm, or from 5 to 500 μm.

The present invention further provides producing an LED display including an LED array according to the invention.

The invention further provides an LED array comprising a semiconductor layer, a dielectric layer extending over the semiconductor layer and having an array of holes through it, and an LED device formed in each of the holes.

The present invention further provides an LED display comprising and LED array according to the invention.

### BRIEF DESCRIPTION OF THE DRAWINGS

FIG. 1a shows an as-grown template formed in a process according to a first embodiment of the invention;

FIG. 1b shows the template of FIG. 1a with a masking pattern formed in its mask layer;

FIG. 1c shows the template of FIG. 1a with micro-LEDs grown in holes in the mask layer;

FIG. 1d shows the template of FIG. 1c with electrical contacts formed on it;

FIG. 2a shows an as-grown template formed in a process according to a second embodiment of the invention;

FIG. 2b shows the template of FIG. 2a with a masking pattern formed in its mask layer;

FIG. 2c shows the template of FIG. 2a with micro-LEDs grown in holes in the mask layer;

FIG. 2d shows the template of FIG. 2c with electrical contacts formed on it;

FIG. 3 is a section through an LED structure of the template of FIG. 2d;

FIG. 4 is a scanning electron microscope image of an LED array according to an embodiment of the invention;

FIG. 5 shows the electro-luminescence spectra of an LED array according to an embodiment of the invention; and

FIG. 6 shows variation of internal quantum efficiency of embodiments of the invention as a function of LED diameter.

### DETAILED DESCRIPTION

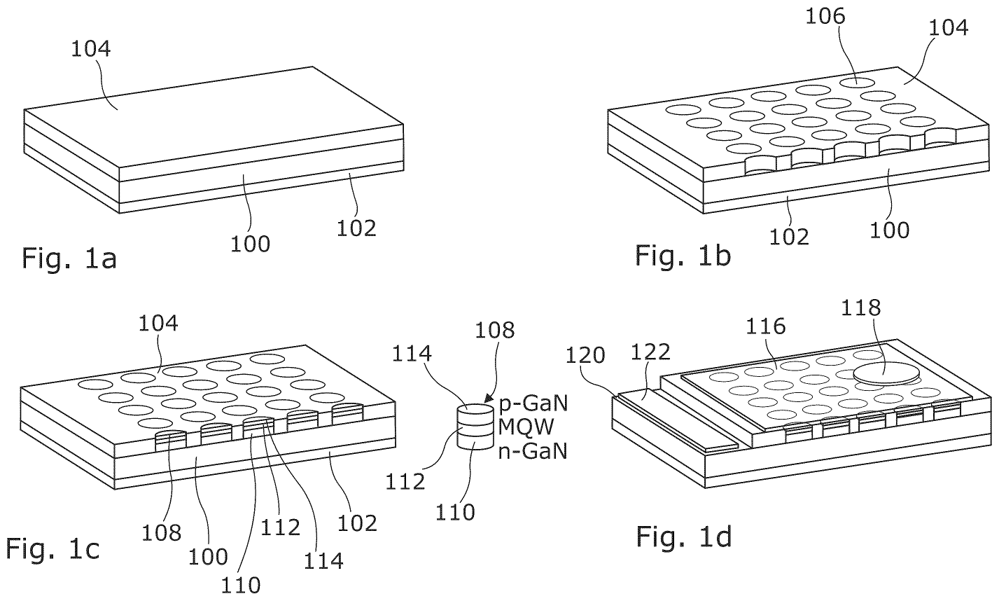

Referring to FIG. 1a, in a first embodiment of the invention a semiconductor layer, for example a standard n-type GaN (n-GaN) layer 100, is initially grown on a substrate 102. The substrate 102 may be a GaN substrate, or may be any foreign substrate such as sapphire, silicon (Si), silicon carbide (SiC) or even glass. The GaN layer 100 may be grown by means of any standard GaN growth method using either metal-organic vapour phase epitaxy (MOVPE) or molecular beam epitaxy (MBE), or any other suitable growth technique. The resulting “as-grown n-GaN template” may have a thickness of above 10 μm, but typically the thickness is in the range from 500 nm to 10 μm. Subsequently, a dielectric layer 104 such as silicon dioxide (SiO₂) or silicon nitride (SiN), or any other suitable dielectric material, is deposited on the n-GaN layer 100 by using PECVD or any other suitable deposition technique. The thickness of the dielectric layer may be in the range from 20 nm to 500 μm.

Referring to FIG. 1b, an array of holes 106 is then formed in the dielectric layer 104. The holes 106 are typically on the micrometer scale and therefore referred to as micro-holes. This may be done by means a photolithography technique and then etching processes (which can be dry-etching or wet-etching). The use of photolithography is advantageous as it allows the holes, and hence the LEDs formed in them, to be accurately formed, with the desired positions, shapes, and sizes. In forming the micro-holes 106, the dielectric layer 104 is etched through its entire thickness down to the upper surface of the n-GaN layer 100. The micro-hole diameter may be from 1 μm to 500 μm, or from 3 μm to 500 μm, and the pitch distance, i.e. the distance between the centres of closest adjacent micro-holes, may be, for example, from 4 μm to 500 μm. Further etching, of the n-GaN layer 100, only within the micro-hole areas, may be performed using the remained dielectric layer 104 as a mask. The n-GaN etching depth can be from zero (meaning there is no GaN etching) to 10 μm, depending on the n-GaN layer thickness. Typically the optimum etching method or conditions will be different for the n-GaN layer than for the dielectric layer. For example SF₆ etching can be used to etch the dielectric layer 104, but will not etch the n-GaN layer 100. Therefore etching all of the way through the dielectric layer 104 and stopping at the top surface of the semiconductor layer 100 is simple to achieve. This also has advantages for the quality of the LED structures grown in the holes 106.

The holes 106 are of a round, specifically circular, cross section in the embodiment shown, but other cross sections may be used, for example oval or square.

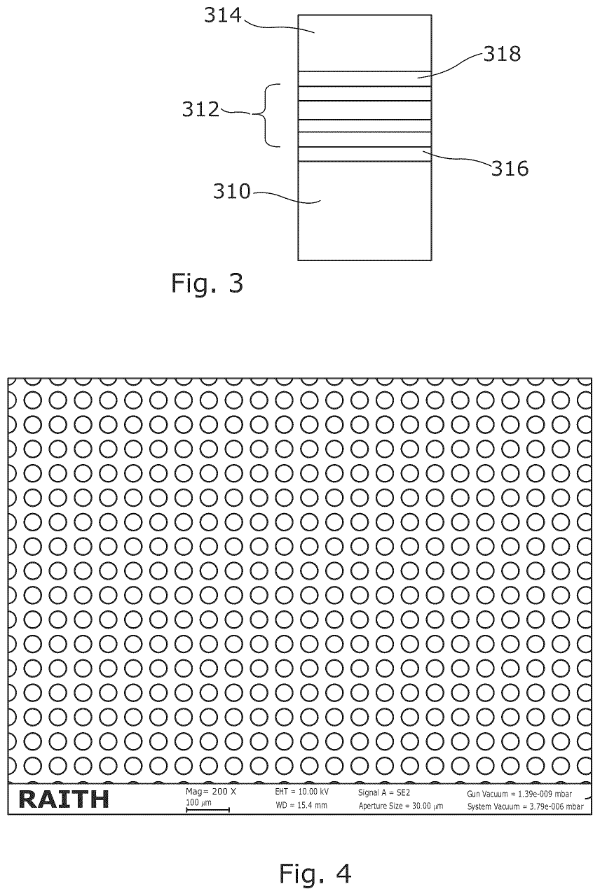

Next, referring to FIG. 1c, a standard III-nitride LED structure is grown on the exposed areas of the GaN layer 100. However, because only discrete areas of the GaN layer 100 are exposed by the micro-holes 106 in the dielectric layer or mask, the LED structures are formed as an array of discrete LEDs 108, separated by the remaining parts of the dielectric layer 104 between the micro-holes 106. The LED structures 108 are grown by either MOVPE or MBE techniques, or any other suitable growth technique. The growth occurs upwards from the exposed areas of the GaN (or other semiconductor) layer, and not from the side walls of the holes 106. Therefore the layered LED structure can be built up inside each of the holes 106 with each of the layers being substantially flat or planar. The LED structures may comprise an n-GaN layer 110, an active region 112, and then a final p-doped GaN layer 114. The active region 112 may comprise InGaN prelayers, InGaN based multiple quantum wells (MQWs), and a thin p-type AlGaN layer as a blocking layer (not shown). An example of an LED structure is described in more detail below with reference to FIG. 3. As mentioned above, due to the dielectric mask 104, the LED structures can be grown only within the micro-holes 106, as shown in FIG. 1c, forming a μLED array.

It is important that the uppermost layer of the InGaN MQWs 112 should not extend above the upper surface of the dielectric layer 104, which could result in a short-circuit effect after the template is fabricated into a final μLED array. It is also important that the overgrown n-GaN 110 within each of the micro-hole areas directly contact the n-GaN layer 100 within the un-etched parts of the template below the dielectric mask 104 so that all the individual μLEDs are electrically connected to each other through the n-GaN layer 100 of the un-etched parts below the dielectric mask 104.

Referring to FIG. 1d, once the LED array structure is completed, further device fabrication is carried out, including the formation of electrical contacts for the array. For example an upper contact layer 116 may be formed over the dielectric mask layer 104 and over the upper p-GaN layer of the individual micro-LED devices 108. The upper contact layer 116 therefore forms a common p-contact for all of the LED devices 108. The upper contact layer 116 may be formed of ITO or Ni/Au alloys. An anode 118 may then be formed on the p-contact layer 116. For example, a part of the dielectric layer 104 may be etched away and then the part of the LED structure on the etched dielectric layer section may be also etched down to the n-GaN, exposing an area 120 of the n-GaN 100, and a cathode 122 formed on that exposed area 120 of n-GaN.

If the LED array is to be used in a display, the continuous contact layer 116 may be replaced by a number of separate contact layer areas each of which covers a respective group of the LED structures 108. Each group may comprise just one LED structure 108 or it may comprise a plurality of LED structures, for example two or three or four. The contact layer areas are electrically isolated from each other, for example by being spaced apart from each other. This allows each group of LED structures to be addressable, i.e. to be switched on and off independently of the others. Specifically each of the contact layer areas can be connected to a respective switching device so as to form a display in which each of the LEDs or groups of LEDs forms a pixel. The accurate control of the location and size and shape of the LED structures provided by photolithography is important in ensuring that the contact layer areas can be aligned correctly with the LED structures to enable them to be individually addressed.

It has been found that, as the overgrowth of the LED structures takes place only within the micro-hole areas 106, the growth rate during formation of the LED devices is significantly increased, compared with those grown under identical conditions on a planar template without any patterning features, in some cases about four times faster.

It will be appreciated that various modifications to the embodiments described above can be made. For example, in one modification the structure is inverted, with a p-GaN layer being grown on the substrate and covered by the dielectric layer, and then the p-GaN layer of the LED devices 108 being formed first, followed by the multiple quantum well layers, and then the n-GaN layer. An n-contact layer is then formed over the top of the dielectric layer in place of the p-contact layer, and the positions of the anode and cathode are reversed.

In the configuration of FIGS. 1a to 1d, the overgrown n-GaN 110 within the micro-holes 106 has to match the n-GaN of the un-etched parts of the n-GaN layer 100 below the dielectric mask 104 so that all the individual μLEDs 108 are electrically connected to each other through the n-GaN layer 100. Instead of using the n-GaN 100 of the un-etched n-GaN parts below the dielectric mask 104 as an electrically connected channel, in a further embodiment, a Group III nitride heterostructure with a two dimensional electron gas (2DEG) at the heterojunction is used as the semiconductor layer, instead of the n-GaN layer. In this embodiment a standard AlGaN/GaN HEMT structure is used. The electron gas (2DEG) with a high sheet carried density and high electron mobility formed at the interface between the AlGaN barrier and the GaN buffer of a HEMT structure is used as an electrically connected channel.

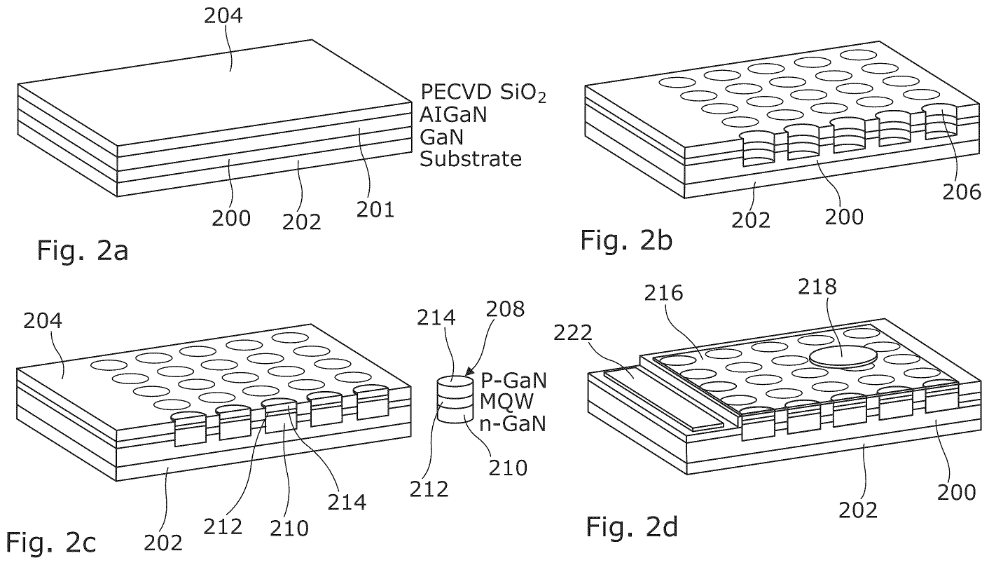

Referring to FIGS. 2a to 2d, in order to produce such a device, a standard AlGaN/GaN HEMT structure is initially grown on GaN a substrate or any foreign substrates such as sapphire, Si, SiC or even glass by means of any standard GaN growth approach using either MOVPE or MBE technique or any other epitaxy technique. Specifically in this embodiment a GaN layer 200 forming a buffer layer is grown on the substrate 202 and then an AlGaN layer 201 forming a barrier layer is grown on the GaN layer 200. This structure is referred to herein as an “as-grown HEMT template”. Subsequently, a dielectric layer 204 such as SiO₂ or SiN or any other dielectric material, for example with a thickness in the range from 2 nm to 500 μm, is deposited on the as-grown HEMT template by using PECVD or any other suitable deposition technique. After that, by means of a photolithography technique and then etching processes (which can be dry-etching or wet-etching) the dielectric layer 204 is etched down to the surface of the HEMT structure to form a micro-hole array 206 in the dielectric layer 204, where the micro-hole diameter can be from several μm to 500 μm, and the pitch distance between adjacent hole centres may be in the range from 10 μm to 500 μm. Further etching the as-grown HEMT within the micro-hole areas can be performed using the remained regions of the dielectric layer 204 as a mask. The as-grown HEMT etching depth can be from zero (meaning there is no any etching) to 10 μm, depending on the AlGaN barrier position of the as-grown HEMT template. However, generally the etching will extend downwards at least as far as the hetero-interface between the two layers 200, 201 of the as-grown HEMT structure, so as to provide good electrical contact between each of the LED structures and the 2DEG.

Next, a standard III-nitride LED structure is grown on the dielectric mask patterned HEMT template featured with micro-holes by either MOVPE or MBE technique or any other epitaxy technique. This may, for example, include growing an n-GaN layer, InGaN prelayers, InGaN based MQWs as an active region, and then a thin p-type AlGaN as a blocking layer and then final p-doped GaN. Due to the dielectric mask, the LED structure grows only within the micro-holes 206, forming discrete micro-LED devices 208 within the micro-holes, as shown in FIG. 2c.

As with the embodiment of FIG. 1a to 1d, an important point is that the upper surface of the InGaN MQWs 212 should be below the upper surface of the dielectric layer 204 so as to avoid a short-circuit effect after being fabricated into final μLED arrays.

Referring to FIG. 3, the LED structures in the LED arrays of FIGS. 1a to 1d and 2a to 2d, may have any suitable structure, but in one example they may include the n-GaN layer 310, an InGaN prelayer 316 formed over the n-GaN layer 310, a number of InGaN quantum well layers 312 formed over the prelayer 316, a p-doped blocking layer 318, for example of p-AlGaN, and then the p-GaN layer 314. It will be appreciated that this structure can be varied in a number of ways. As indicated above, it is preferable that the top of the uppermost one of the quantum well layers 312 is below the top of the dielectric layer. It is also preferable that the top of the blocking layer 318 is also below the top of the dielectric layer.

Another important point is that the overgrown n-GaN within the micro-hole areas directly contacts the interface between the AlGaN barrier and the GaN buffer of the initially as-grown HEMT structure of the un-etched parts below the dielectric mask 204 so that all the individual μLEDs are electrically connected through the 2DEG formed at the interface between the AlGaN barrier and the GaN buffer of the HEMT structure below the dielectric mask (i.e. the un-etched parts). Once the LED structure is completed, any suitable standard device fabrication may be carried out, as with the embodiment of FIGS. 1a to 1d and each device will include a number of individual μLED components as shown in FIG. 2d where all the individual μLEDs 208, which are separated by the remained dielectric mask 204 in order to eliminate a short circuit in each device, share a common p-contact 216.

It should be noted that, in the embodiment of FIGS. 2a to 2d, prior to any standard LED fabrication steps, a selective etching of the dielectric mask 204 may be required in order to let part of the surface of the HEMTs structure be exposed, where a cathode contact 222 will be fabricated on the surface of the exposed HEMTs as shown in FIG. 2d. The selective etching can be dry-etching or wet-etching.

As an example, FIG. 4 shows a typical scanning microscope image of a μLED array epi-wafer, produced as described above, where the diameter of each μLED is 40 μm.

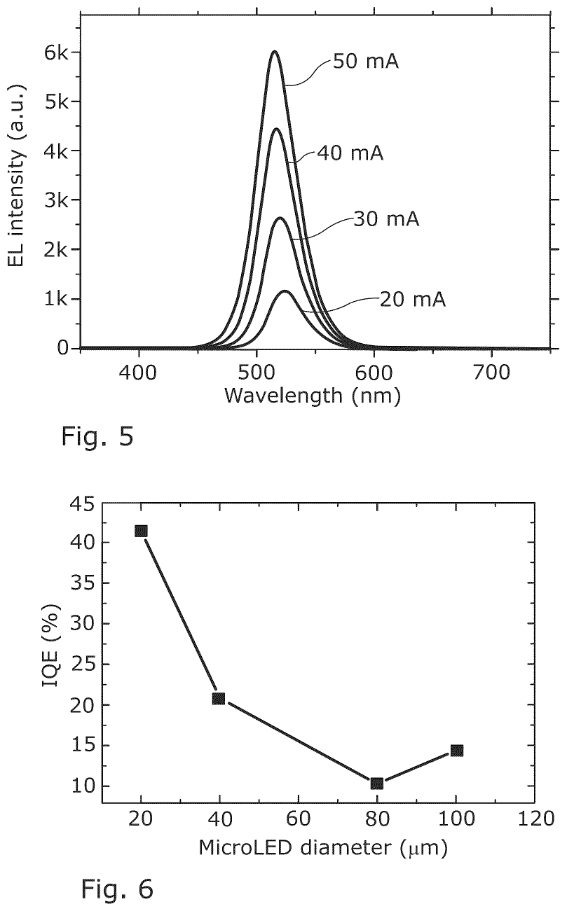

As an example, FIG. 5 shows electro-luminescence spectra of a μLED with a diameter of 40 μm as a function of injection current.

FIG. 6 shows the internal quantum efficiency (IQE) of μLEDs formed as described above, measured as a function of the diameter of μLEDs. This shows that the IQE of the LEDs increases with decreasing the diameter of μLED. The results are different from those of all previous μLEDs which are fabricated using conventional approaches. This suggests that the methods described above have avoided dry-etching induced sidewall damages typically generated during conventional fabrication processes.

1. A method comprising:
forming a buffer layer comprising a Gallium Nitride (GaN) material;
forming a barrier layer comprising a GaN material above the buffer layer, such that a hetero-interface is defined between the buffer layer and the barrier layer, the hetero-interface being arranged to form a two-dimensional charge carrier gas;
forming a dielectric layer over the barrier layer, the dielectric layer defining an array of holes through the dielectric layer, each hole exposing a respective area of the barrier layer, each of the holes having a respective width of between 1 μm and 40 μm; and
in each of the holes:
growing a first semiconductor layer on the area of the barrier layer that is exposed by the hole, the first semiconductor layer having a p-type or n-type conductivity type that matches a p-type or n-type conductivity type of the area of the barrier layer where the first semiconductor layer is grown;
growing at least one light emitting diode (LED) active layer within the hole above the first semiconductor layer; and
growing a second semiconductor layer within the hole above the at least one LED active layer, the second semiconductor layer having a p-type or n-type conductivity type that is different from the p-type or n-type conductivity type of the first semiconductor layer.

2. The method of claim 1, wherein the at least one LED active layer formed within each hole has an upper surface which is below a top of the dielectric layer.

3. The method of claim 1, wherein the forming of the dielectric layer comprises:
growing the dielectric layer; and
etching the array of holes into the dielectric layer.

4. The method of claim 1, further comprising:
forming a plurality of contact layer areas above the dielectric layer, each of the contact layer areas providing an electrical contact for the second semiconductor layers formed in a respective subset of the holes.

5. The method of claim 1, wherein:
the buffer layer comprises GaN.

6. The method of claim 5, wherein:
the barrier layer comprises Indium Gallium Nitride (InGaN).

7. The method of claim 5, wherein:
the barrier layer comprises Aluminum Gallium Nitride (AlGaN).

8. The method of claim 1, wherein:
the buffer layer comprises Aluminum Gallium Nitride (AlGaN) having a first concentration of Aluminum; and
the barrier layer comprises AlGaN having a second concentration of Aluminum, the second concentration being greater than the first concentration.

9. The method of claim 1, wherein:
the buffer layer comprises Indium Gallium Nitride (InGaN) having a first concentration of Indium; and
the barrier layer comprises InGaN having a second concentration of Indium, the second concentration being greater than the first concentration.

10. The method of claim 1, wherein:
the two-dimensional charge carrier gas comprises a two-dimensional electron gas.

11. The method of claim 1, wherein:
the two-dimensional charge carrier gas comprises a two-dimensional hole gas.

12. An LED array, comprising:
a buffer layer comprising a Gallium Nitride (GaN) material;
a barrier layer comprising a GaN material formed above the buffer layer, such that a hetero-interface is defined between the buffer layer and the barrier layer, the hetero-interface being arranged to form a two-dimensional charge carrier gas;
a dielectric layer formed over the barrier layer, the dielectric layer defining an array of holes through the dielectric layer, each hole exposing a respective area of the barrier layer, each of the holes having a respective width of between lum and 40 μm; and
in each of the holes:
a first semiconductor layer formed on the area of the barrier layer that is exposed by the hole, the first semiconductor layer having a p-type or n-type conductivity type that matches a p-type or n-type conductivity type of the area of the barrier layer where the first semiconductor layer is grown;
at least one light emitting diode (LED) active layer formed within the hole above the first semiconductor layer; and
a second semiconductor layer formed within the hole above the at least one LED active layer, the second semiconductor layer having a p-type or n-type conductivity type that is different from the p-type or n-type conductivity type of the first semiconductor layer.

13. The LED array of claim 12, wherein the at least one LED active layer formed within each hole has an upper surface which is below a top of the dielectric layer.

14. The LED array of claim 12, further comprising:
a plurality of contact layer areas formed above the dielectric layer, each of the contact layer areas providing an electrical contact for the second semiconductor layers formed in a respective subset of the holes.

15. The LED array of claim 12, wherein:
the buffer layer comprises GaN.

16. The LED array of claim 15, wherein:
the barrier layer comprises Indium Gallium Nitride (InGaN).

17. The LED array of claim 15, wherein:
the barrier layer comprises Aluminum Gallium Nitride (AlGaN).

18. The LED array of claim 12, wherein:
the buffer layer comprises Aluminum Gallium Nitride (AlGaN) having a first concentration of Aluminum; and
the barrier layer comprises AlGaN having a second concentration of Aluminum, the second concentration being greater than the first concentration.

19. The LED array of claim 12, wherein:
the buffer layer comprises Indium Gallium Nitride (InGaN) having a first concentration of Indium; and
the barrier layer comprises InGaN having a second concentration of Indium, the second concentration being greater than the first concentration.

20. An LED display comprising an LED array, the LED array comprising:
a buffer layer comprising a Gallium Nitride (GaN) material;
a barrier layer comprising a GaN material formed above the buffer layer, such that a hetero-interface is defined between the buffer layer and the barrier layer, the hetero-interface being arranged to form a two-dimensional charge carrier gas;
a dielectric layer formed over the barrier layer, the dielectric layer defining an array of holes through the dielectric layer, each hole exposing a respective area of the barrier layer, each of the holes having a respective width of between lum and 40 μm; and
in each of the holes:
a first semiconductor layer formed on the area of the barrier layer that is exposed by the hole, the first semiconductor layer having a p-type or n-type conductivity type that matches a p-type or n-type conductivity type of the area of the barrier layer where the first semiconductor layer is grown;
at least one light emitting diode (LED) active layer formed within the hole above the first semiconductor layer, and
a second semiconductor layer formed within the hole above the at least one LED active layer, the second semiconductor layer having a p-type or n-type conductivity type that is different from the p-type or n-type conductivity type of the first semiconductor layer.
